(19) United States
(12) Patent Application Publication
(10) Pub. No.: US 2002/0125043 A1
(43) Pub. Date: Sep. 12, 2002

(54) Semiconductor packaging structure, packaging board and inspection method of packaging conditions

(76) Inventor: Yuichi Yoshida, Tokyo (JP)

Correspondence Address: Sughrue Mion Zinn Macpeak & Seas PPLC, 2100 Pennsylvania Avenue NW, Washington, DC, 20037-3213, US

(21) Appl. No.: 09/906,403

(22) Filed: Mar. 20, 2001

(30) Foreign Application Priority Data
Aug. 29, 1996 (JP) 228933/1996

(51) Int. Cl. H05K 7/02; H05K 7/06

(52) U.S. Cl. 174/261; 174/250; 361/777

(57) ABSTRACT

According to this invention, a semiconductor device is mounted on a board by providing on the board connecting pads each split into at least two parts corresponding to one external electrode formed on the semiconductor device, and connecting each of the external electrodes to respective parts of the connecting pad split into at least two parts via a solder bump. Further, the split parts of the connecting pad are connected respectively to separate external terminals via internal wirings provided within the board.

The connecting conditions of the packaging structure of the semiconductor device in which the external electrodes are connected to the connecting pads via solder bumps is confirmed by inspecting the electric continuity conditions between the parts of the connecting pads each split into at least two parts or the electrical continuity conditions between the external terminals connected to the split parts of the connecting pads.

Moreover, the external terminals are provided on the peripheral portion of the board, a separation assisting structure is provided between the peripheral portion of the surface of the board where the external terminals are provided and the portion of the surface of the board where the connecting pads are formed, and the peripheral portion of the board is deleted after the inspection of the electrical continuity conditions between the external terminals is completed.

### BACKGROUND OF THE INVENTION

1. Field of the Invention

The present invention relates to a semiconductor packaging structure, a packaging board and an inspection method of packaging conditions in the packaging of a semiconductor chip by the face-down connection technique or by means of a ball grid array (BGA).

2. Description of the Related Art

Heretofore, in the packaging structure of the above kind for a semiconductor device, one electrode formed on a semiconductor chip or a BGA package and one pad formed on a packaging board are made to correspond on one-to-one basis.

Here, referring to a drawing, a conventional packaging structure of a semiconductor device will be described.

Referring to FIG. 7, external electrodes 2 of a semiconductor chip 1 correspond to packaging pads 5 on a wiring board 4 for mounting the semiconductor chip 1 on one-to-one basis, and the external electrodes 2 and the packaging pads 5 are connected via solder bumps 3. The packaging pads 5 of the wiring board 4 are wired to other external pads 6 using internal wirings 7.

Furthermore, the technique relating to this invention is disclosed in Publication of Unexamined Patent Application Laid-Open No. H6-310565. In this prior art packaging structure, a semiconductor device and a wiring board are connected by making a plurality of bumps correspond to one bump. However, this structure is similar to the prior art shown in FIG. 7 so far as the circumstance goes in which one electrode is formed on the wiring board corresponding to one electrode formed on the semiconductor device on one-to-one basis.

In the packaging structure of this prior art, it is extremely difficult to confirm the connection conditions of the semiconductor device and the wiring board even with the use of a microscope or the like, owing to the connection part between the semiconductor device and the wiring board being concealed to the lower side of the semiconductor device. In particular, when the external electrodes are formed on the semiconductor device not only along the periphery of the semiconductor chip but also in double array as shown in FIG. 8, it is impossible to confirm the connection conditions from the outside after the completion of the packaging.

Moreover, in connecting a BGA package instead of a semiconductor chip to the wiring board, the solder bumps of the BGA package are formed in lattice form on the lower surface of the package as shown in FIG. 9, so that it is also impossible to confirm the connection conditions after mounting the package on the wiring board by direct visual inspection from the outside. It should be mentioned that the connection conditions between the BGA package and the wiring board may be investigated based on the size of the shadows of the solder bumps on an image photographed by irradiating the system with X-rays. However, with this method it is almost impossible to examine solder deficiency and opening defect caused by defective solder coating. Although it is possible to observe these defects to some extent by devising the method of X-ray irradiation, it is not applicable to mass production process when problems such as the processing time and the cost are taken into consideration.

### SUMMARY OF THE INVENTION

In order to resolve the above problems, the packaging structure of the semiconductor device according to this invention is obtained by providing on the board a connecting pad split into at least two parts corresponding to one external electrode formed on the semiconductor device, and connecting the external electrode to the connecting pad of the board via a bump.

In addition, the inspection method of the connecting conditions according to this invention inspects the connection conditions between the solder bumps and the connecting pads by inspecting the electrical continuity conditions between parts of the connecting pads split into two or more parts in the above-mentioned packaging structure of the semiconductor device.

According to the packaging structure of this invention, the connecting pads on the wiring board for connecting the bumps formed on the electrodes of the semiconductor device are so constructed as to be split into plural parts and connected to respectively separate external terminals. The connection conditions between the semiconductor device and the wiring board which cannot be judged from its appearance can readily be confirmed by inspecting the electrical continuity conditions between the external terminals.

### BRIEF DESCRIPTION OF THE DRAWINGS

The above and other objects, features and advantages of the present invention will become more apparent from the following detailed description taken with the accompanying drawings in which:

FIG. 1 is a sectional view showing the configuration of a first embodiment of this invention;

FIG. 2 is a plan view showing the configuration of the wiring board in FIG. 1;

FIG. 3 is a sectional view showing the configuration of a second embodiment of this invention;

FIG. 4 is a plan view showing the configuration of a third embodiment of this invention in which part (a) shows the configuration of the wiring board before deletion of the outside portion, and part (b) shows the configuration of the wiring board after the deletion of the outside portion;

FIG. 5(a)˜5(f) is a diagram showing various other examples of the shape of the connecting pad;

FIG. 6(a)˜6(b) is a diagram showing other examples of the layout of external pads;

FIG. 7 is a sectional view showing a conventional packaging structure of the semiconductor device;

FIG. 8 is a plan view showing the arrangement of external electrodes formed on the semiconductor chip; and

FIG. 9 is a plan view showing the arrangement of solder bumps formed on the BGA package.

### DETAILED DESCRIPTION

Referring to the drawings, a first embodiment of this invention will be described in detail next.

This embodiment is for mounting a semiconductor chip on a wiring board, in particular for connecting one electrode formed on the semiconductor chip by making it correspond to at least two parts of the connecting pads formed on the wiring board. The connection conditions of the semiconductor chip and the wiring board is inspected by examining the electrical continuity conditions between the connecting pads connected to one electrode on the semiconductor chip.

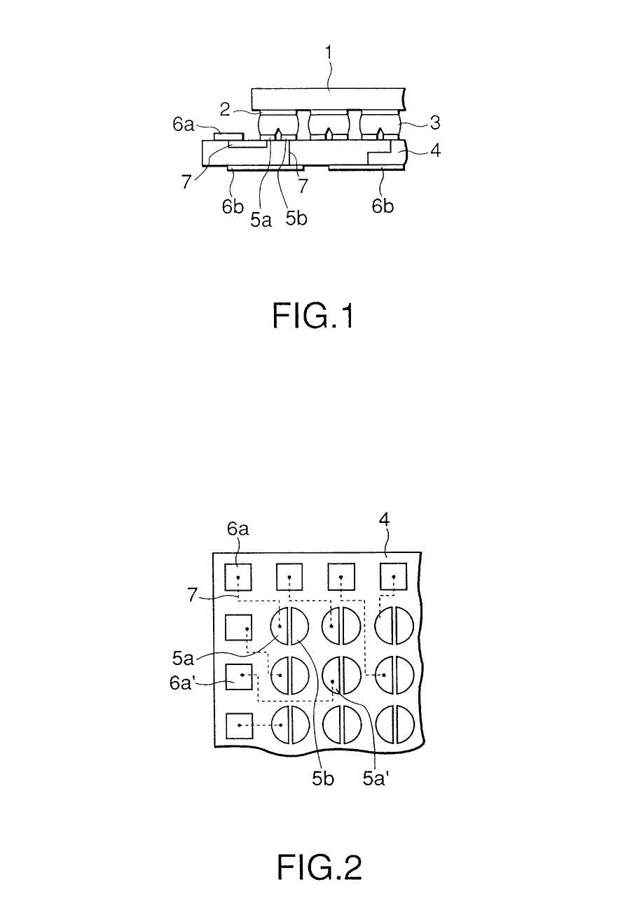

FIG. 1 is a diagram showing the packaging structure of this embodiment, and FIG. 2 is a plan view showing the wiring board indicated in FIG. 1. Referring to FIG. 1, a semiconductor chip 1 is connected to two connecting pads 5a and 5b formed on a wiring board 4 via a solder bump 3 formed on an external electrode 2. The solder bump 3 is formed of a solder material such as Sn/Pb, Sn/Ag or Sn/In. In addition, the wiring board 4 is formed of a printed board, ceramic board, flexible board or the like. The connecting pads 5a and 5b are formed of a metal with excellent electrical conduction such as gold or copper, or a material obtained by coating such a metal with solder, and the two semicircular parts formed by bisecting a circular pad constitute a pair. The combined outer shape of the two semicircular pads has a shape substantially the same as that of the electrode 2 of the semiconductor chip 1.

The two connecting pads 5a and 5b formed on the wiring board 4 so as to correspond to one of the electrodes 2 formed on the semiconductor chip 1 are connected to separate external pads 6a and 6b by means of internal wirings 7. Here, the external pad 6a is formed on the surface on the semiconductor chip 1 side of the wiring board 4, whereas the external pad 6b is formed on the surface (rear surface) opposite to the surface on which the external pad 6a is formed.

The connecting pads Sa and 5b will be connected with each other via the solder bump 3 if the connection conditions between the semiconductor chip 1 and the wiring board 4 is satisfactory. Accordingly, it is possible to confirm the sure connection of the solder bump 3 to the connecting pads 5a and 5b by inspecting the electrical continuity conditions between the external pads 6a and 6b connected to the connecting pads 5a and 5b.

Referring to FIG. 2, the external pads 6a for inspecting the electrical continuity conditions connected to the connecting pads 5a formed on the wiring board 4 are provided in the peripheral part of the wiring board 4. In particular, external pads 6a′ for electrical continuity inspection connected to connecting pads 5a′ formed in the interior on the surface of the wiring board 4 are also provided in the peripheral part of the wiring board 4. Accordingly, the connection conditions between the wiring board 4 and the electrodes formed in the interior of the semiconductor chip 1 can readily be confirmed by inspecting the electrical continuity conditions between the external pads 6a (6a′) provided in the peripheral part on the surface of the wiring board 4 and the external pads 6b provided on the rear surface of the wiring board 4.

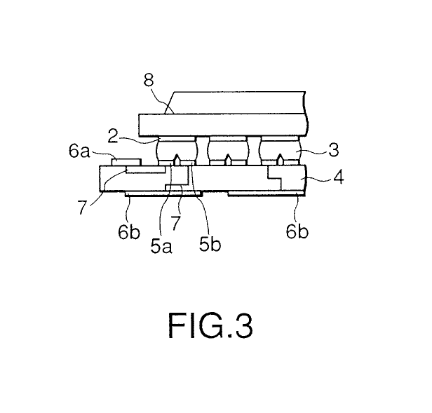

Next, referring to FIG. 3, a second embodiment of this invention will be described.

The packaging structure of this embodiment is similar to that of the first embodiment for the most part, except that a BGA package 8 is mounted on the wiring board 4 instead of mounting a semiconductor chip 1 on the wiring board 4, so a detailed description will be omitted. In other words, the packaging structure of this invention is also applicable to the case of mounting a BGA package on a wiring board.

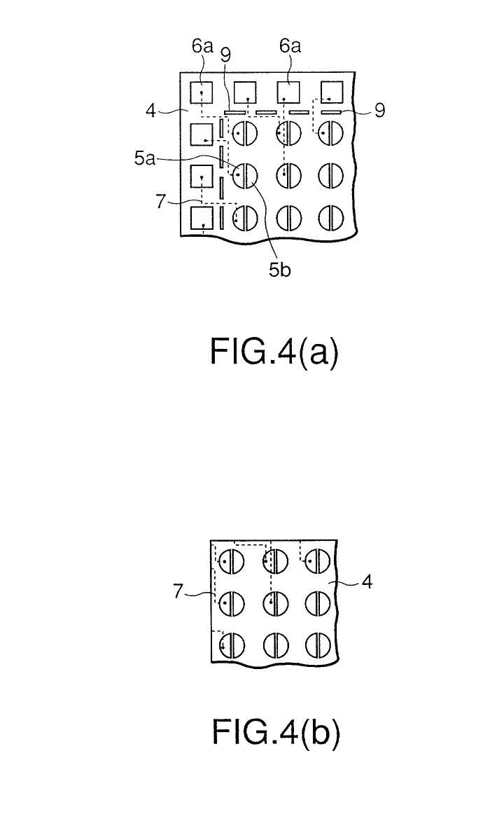

Next, referring to FIGS. 4(a) and 4(b), a third embodiment of this invention will be described.

FIG. 4(a) is a plan view showing the configuration of a wiring board used in this embodiment, where the embodiment has a special feature in the wiring board, and the first embodiment is applicable to the remaining parts. Accordingly, a detailed description regarding the constitution will be omitted for the parts other than the wiring board 4.

Referring to FIG. 4(a), the external pads 6a connected to the connecting pads 5a by the internal wirings 7 are installed in the peripheral part of the region where the connecting pads 5a and 5b are formed on the wiring board 4. In addition, dividing grooves 9 for cutting off the peripheral part where external pads 6a are formed from the wiring board 4 are provided between the region where the connecting pads 5a and 5b are formed and the peripheral part where the external pads 6a are formed.

After establishing connecting between the semiconductor chip 1 and the wiring board 4, it is possible to remove the outer portion where the external pads 6a of the wiring board 4 are formed by cutting the wiring board 4 along the dividing grooves 9. The constitution of the wiring board 4 after deletion of the external pads 6a is shown in FIG. 4(b).

By the deletion of the external pads 6a, it is possible to confirm the connection conditions between the semiconductor chip 1 and the wiring board 4 without making the size of the wiring board 4 more than necessary. Moreover, the most part of excess internal wirings from the connecting pads 5a to the external pads 6a can also be deleted at the same time, so that adverse effect on electrical characteristics caused by the external pads 6a and the internal wirings 7 can be reduced.

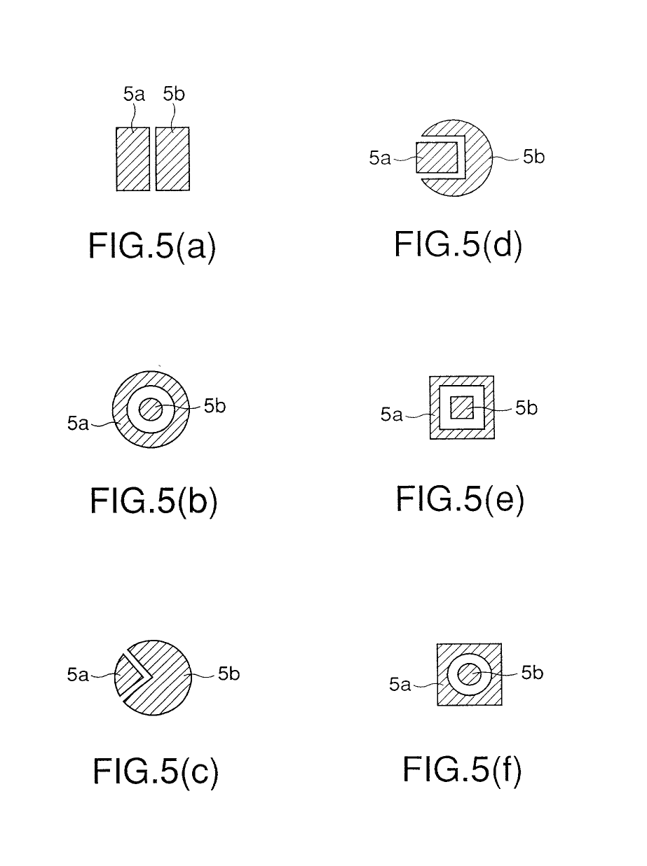

Furthermore, in the first to the third embodiments, semicircular connecting pads obtained by bisecting a circular pad are used as the connecting pads to be formed on the wiring board 4, but the shape of the connecting pads is not limited to this kind only. The connecting pads applicable to this invention includes those as shown in FIGS. 5(a) through 5(f).

FIG. 5(a) is an example in which the connecting pad is chosen to be a rectangle which is bisected. FIG. 5(b) is an example in which a circular pad is divided into an inner and an outer parts by a concentric circle as the dividing line. FIG. 5(c) is an example in which a circular pad is divided into two parts by a dividing line which partitions a sector. FIG. 5(d) is an example in which a circular pad is divided into two parts by a rectangular dividing line whose one side makes contact with the circle. FIG. 5(e) is an example in which a rectangular pad is divided into two parts by a rectangular dividing line drawn within the pad. FIG. 5(f) is an example in which a rectangular pad is divided into two parts by a circular dividing line drawn within the pad.

Moreover, a set of two connecting pads are provided corresponding to one external electrode formed on the semiconductor device. However, needless to say, connecting pads consisting of pads divided into three or more parts regarded as one set may also be employed.

Further, the separation X between the divided connecting pads 5a and 5b is preferably 10-50 μm in the case of mounting a semiconductor chip, and 50-200 μm in the case of mounting a BGA package.

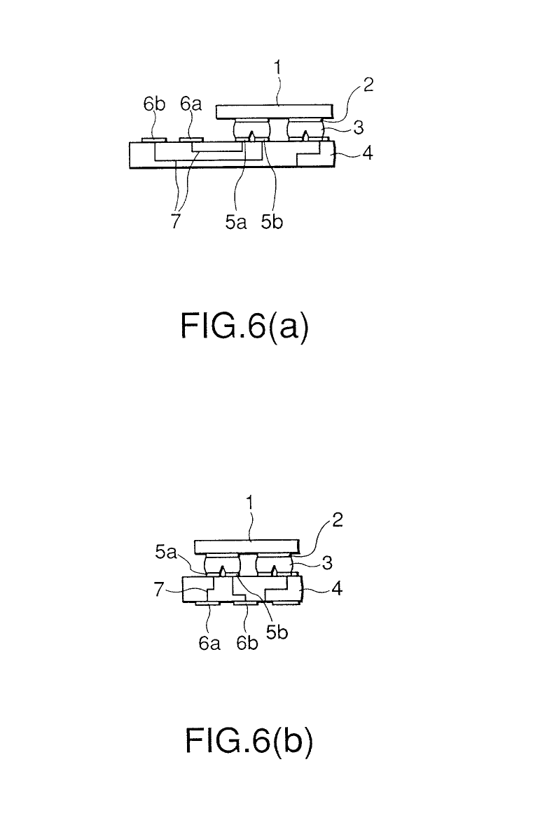

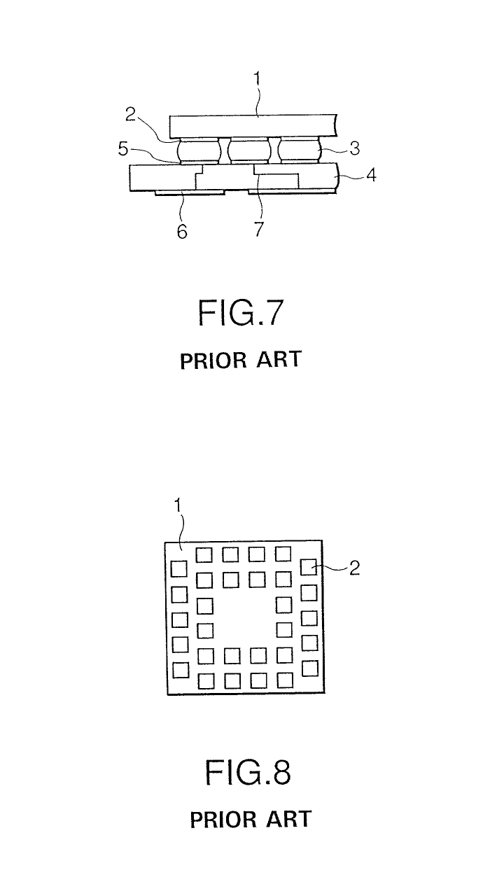

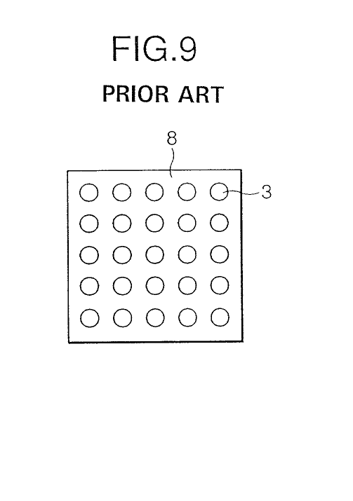

Further, in the first to the third embodiments, the external pads 6a and 6b are formed respectively on the mutually opposing surfaces of the wiring board 4 However, the method of providing these pads is not limited to this type only, and a constitution in which both pads are formed in the peripheral part on the semiconductor chip 1 side of the wiring board 4 as shown in FIG. 6(a). Otherwise, both of the external pads 6a and 6b may be formed on the rear surface of the wiring board 4 as shown in FIG. 6(b).

Still further, other external terminals such as pins and leads, instead of terminals with pad structure such as the external pads, may be connected to the connecting pads.

As described in the above, according to the packaging structure of a semiconductor device of this invention, the connecting pads on the wiring board side for connecting the solder bumps formed on the semiconductor device are so constructed as to be divided into plural parts and respective parts connected to separate external terminals. By inspecting the conduction conditions between the external terminals, it is possible to readily confirm the connection conditions of the semiconductor device and the wiring board which cannot be judged from appearance.

What is claimed is:

1. A packaging structure for mounting a semiconductor device on a board characterized in that a connecting pad split into at least two parts is provided on the board so as to correspond to one external electrode formed on the semiconductor device and said external electrodes are connected respectively to said connecting pads divided into at least two parts.

2. The packaging structure for a semiconductor device as claimed in claim 1 in which respective parts of said connecting pad split into at least two parts are connected to separate external terminals on said board via internal wirings provided in the board.

3. The packaging structure for a semiconductor device as claimed in claim 2 in which said external terminals are provided in the peripheral part of said board.

4. The packaging structure for a semiconductor device as claimed in claim 2 in which at least one external terminal out of at least two of said external terminals connected to respective parts of said connecting pad split into at least two parts is provided on the surface opposite to the surface of said board where said connecting pad is formed.

5. The packaging structure for a semiconductor device as claimed in claim 2 in which the overall outer shape of said connecting pad split into at least two parts is substantially the same as the outer shape of said external electrode.

6. The packaging structure for a semiconductor device as claimed in claim 2 in which said connecting pad split into at least two parts is split by a dividing line of linear, rectangular, circular or sectorial shape drawn in the interior of a rectangular or circular pad.

7. The packaging structure for a semiconductor device as claimed in claim 3 in which a separation assisting structure is provided between the peripheral portion of the surface of said board where said external terminals are formed and the portion of the surface of said board where said connecting pads are formed.

8. The packaging structure for a semiconductor device as claimed in claim 7 in which said separation assisting structure consists of a plurality of grooves.

9. A packaging board for mounting a semiconductor device characterized in that a connecting pad split into at least two parts is provided on a board corresponding to one external electrode formed on the semiconductor device, and the split parts of said connecting pad are respectively connected to separate external terminals on said packaging board via internal wirings.

10. The packaging board as claimed in claim 9 in which said external terminals are formed in the outer portion, and a means for separating said outer portion is provided between the outer portion where said external terminals are formed and the inner portion where said connecting pads are formed.

11. The packaging board as claimed in claim 10 in which said separating means consists of a plurality of grooves.

12. A method for inspecting the connecting conditions of a packaging structure of a semiconductor device, formed by providing, on a board, connecting pads each split into at least two parts corresponding to one external electrode formed on the semiconductor device, and connecting the split parts of said connecting pads to said external electrodes via solder bumps, which is performed by inspecting the electrical continuity conditions between the parts of said connecting pads each split into at least two parts.

13. A method of inspecting the connecting conditions of a packaging structure of a semiconductor device, formed by providing, on a board, connecting pads each split into at least two parts corresponding to one external electrode formed on the semiconductor device, connecting the parts of the connecting pads to respectively separate external terminals on said board via internal wirings provided within said board, and connecting said external electrodes to said connecting pads each split into at least two parts via solder bumps, which is performed by inspecting the electrical continuity conditions between said external terminals connected to the split parts of said connecting pads.

14. The inspection method of the connecting conditions as claimed in claim 13 in which said external terminals are provided in the outer portion of said board and the outer portion of said board is deleted after completion of the inspection of electrical continuity conditions between the external terminals.
